(19) United States
(12) Patent Application Publication
(10) Pub. No.: US 2025/0160067 A1
(43) Pub. Date: May 15, 2025

(54) MICRO LIGHT-EMITTING DIODE, MICRO LIGHT-EMITTING ELEMENT AND PREPARATION METHOD THEREFOR, AND DISPLAY DEVICE

(71) Applicant: Tianjin Sanan Optoelectronics Co., Ltd., Tianjin (CN)

(72) Inventors: Yenchin WANG, Tianjin (CN); Jing WANG, Tianjin (CN); Jinhua CHEN, Tianjin (CN); Huanshao KUO, Tianjin (CN); Yuren PENG, Tianjin (CN)

(21) Appl. No.: 19/021,196

(22) Filed: Jan. 15, 2025

Related U.S. Application Data
(63) Continuation of application No. PCT/CN2022/115586, filed on Aug. 29, 2022.

(51) Int. Cl. H10H 20/84; H10H 20/01; H10H 20/824; H10H 29/85

(52) U.S. Cl. CPC H10H 20/84; H10H 20/824; H10H 29/857; H10H 20/017

(57) ABSTRACT

A micro light-emitting element includes a substrate and at least one micro light-emitting diode. Each micro light-emitting diode includes a semiconductor epitaxial stacked layer, which includes a first-type semiconductor layer, an active layer and a second-type semiconductor layer, and comprises a first surface and a second surface; the first surface is located on a side near the first-type semiconductor layer, the second surface is located on a side near the second-type semiconductor layer, and the first surface faces towards the substrate; and an adhesive film layer, which is located between the substrate and the semiconductor epitaxial stacked layer. An etching protective layer is disposed between the adhesive film layer and the first surface. The micro light-emitting element can reduce damage to the semiconductor epitaxial stacked layer during a residual adhesive removing process after laser lifting-off of each micro light-emitting diode, thus improving reliability of the micro light-emitting element.

### CROSS-REFERENCE TO RELATED APPLICATION

This application is a continuation of International Patent Application No. PCT/CN2022/115586, filed on Aug. 29, 2022, which is herein incorporated by reference in its entirety.

### TECHNICAL FIELD

The disclosure relates to the field of semiconductor manufacturing, and more particularly to a micro light-emitting diode, a micro light-emitting element and a preparation method therefor, and a display device.

### BACKGROUND

Micro light-emitting diodes possess advantages of self-luminescence, high efficiency, low power consumption, high brightness, high stability, ultra-high resolution and color saturation, fast response speed, long lifespan and so on. The micro light-emitting diodes have already been applied in various fields such as display, optical communication, indoor positioning, biology, and medical treatment, and are expected to further expand into wearable/implantable devices, augmented reality/virtual reality, vehicle-mounted displays, ultra-large displays, optical communication/optical interconnections, medical detections, intelligent headlights, spatial imaging and other fields, presenting a clear and substantial market prospect. The mass transfer technology is an indispensable part of micro light-emitting diode (micro-LED) display technology, which mainly transfers micro light-emitting diodes to a specific substrate and assembles them into a two-dimensional periodic array. How to improve optoelectronic performance of the micro light-emitting diodes and a yield rate of the mass transfer is a current technical problem that needs to be solved urgently.

### SUMMARY

In order to solve a problem mentioned in the background, an embodiment of the disclosure provides a micro light-emitting element, which includes: a substrate, and at least one micro light-emitting diode disposed on the substrate; each of the at least one micro light-emitting diode includes: a semiconductor epitaxial stacked layer, including a first-type semiconductor layer, an active layer and a second-type semiconductor layer sequentially arranged in that order; the semiconductor epitaxial stacked layer has a first surface and a second surface that are opposite to each other, the first surface is located on a side of the semiconductor epitaxial stacked layer near the first-type semiconductor layer, the second surface is located on a side of the semiconductor epitaxial stacked layer near the second-type semiconductor layer, and the first surface faces towards the substrate; and an adhesive film layer, disposed between the substrate and the first surface of the semiconductor epitaxial stacked layer. An etching protective layer is disposed between the adhesive film layer and the first surface of the semiconductor epitaxial stacked layer.

Another embodiment of the disclosure provides a preparation method of a micro light-emitting element, which includes steps as follows:

(1) providing a growth substrate, and forming a semiconductor epitaxial stacked layer on the growth substrate; the semiconductor epitaxial stacked layer including a first-type semiconductor layer, an active layer and a second-type semiconductor layer sequentially arranged in that order;

(2) removing a part of the semiconductor epitaxial stacked layer by a dry etching method to form a first mesa and a second mesa, and forming a first electrode and a second electrode on the first mesa and the second mesa respectively to thereby form electrical connections with the first-type semiconductor layer and the second-type semiconductor layer respectively;

(3) fixing/securing a side of the semiconductor epitaxial stacked layer facing away from the growth substrate onto a first transfer substrate through a first adhesive layer, and then removing the growth substrate;

(4) forming an etching protective layer on a surface of the semiconductor epitaxial stacked layer facing away from the first transfer substrate, then providing an adhesive film layer, and fixing/securing the etching protective layer onto a second transfer substrate through the adhesive film layer; and

(5) removing the first adhesive layer and stripping off the first transfer substrate by laser, to thereby expose the first electrode and the second electrode.

Still another embodiment of the disclosure provides a micro light-emitting diode, including: a semiconductor epitaxial stacked layer, which includes a first-type semiconductor layer, an active layer and a second-type semiconductor layer sequentially arranged in that order; the semiconductor epitaxial stacked layer including a first surface and a second surface that are opposite to each other, the first-type semiconductor layer being located on a side of the semiconductor epitaxial stacked layer near the first surface, and the second-type semiconductor layer being located on a side of the semiconductor epitaxial stacked layer near the second surface; an etching protective layer, disposed covering the first surface of the semiconductor epitaxial stacked layer; a first electrode, electrically connected to the first-type semiconductor layer; and a second electrode, electrically connected to the second-type semiconductor layer.

Even still another embodiment of the disclosure provides a display device. The display device includes: a base with a driving circuit; and, at least one the micro light-emitting diode as described above, disposed on the base. Each of the at least one micro light-emitting diode is electrically connected to the driving circuit.

In some embodiments of the disclosure, a case of the etching protective layer being disposed on the first surface of the semiconductor epitaxial stacked layer and another case of the adhesive film layer being inwardly reduced with a certain width are both occurred or only one occurred, but the disclosure is not limited to the illustrated embodiments.

The disclosure may have the following beneficial effects.

1. By setting the etching protective layer, after laser lifting-off the micro light-emitting diode, damage to the semiconductor epitaxial stacked layer during a residual adhesive removing process can be reduced, thereby improving optoelectronic performance and reliability of the micro light-emitting element.

2. By inwardly reducing the adhesive film layer with a certain width, a center of gravity of the micro light-emitting diode is concentrated at a center of the micro light-emitting diode, which can reduce the generation of flip over of the micro light-emitting diode during a transfer process after the laser lifting-off the micro light-emitting element, thereby improving a transfer yield rate of micro light-emitting diode.

### BRIEF DESCRIPTION OF DRAWINGS

FIG. 1 illustrates a schematic diagram of residual adhesive existed on a surface of a micro light-emitting diode in the related art.

FIG. 2 and FIG. 3 illustrate schematic structural diagrams of micro light-emitting elements according to a first embodiment of the disclosure.

FIG. 4 through FIG. 6 illustrate schematic structural diagrams of micro light-emitting elements according to a second embodiment of the disclosure.

FIG. 7 through FIG. 16 illustrate schematic structural diagrams associated with a preparation process of a micro light-emitting element according to a third embodiment of the disclosure.

FIG. 17 illustrates a schematic structural diagram of a micro light-emitting diode according to a fourth embodiment of the disclosure.

FIG. 18 illustrates a schematic structural diagram of a display device according to a fifth embodiment of the disclosure.

Descriptions of numeral references in the drawings are that:

100, growth substrate;

1, semiconductor epitaxial stacked layer;

101, first-type semiconductor layer;

102, active layer;

103, second-type semiconductor layer;

S1, first mesa;

S2, second mesa;

104, first electrode;

105, second electrode;

106, adhesive layer;

107, first transfer substrate;

108, etching protective layer;

109, adhesive film layer;

110, substrate;

A1, first surface;

A2, second surface;

D1, distance between the adhesive film layer and the edge of the first surface;

a1, length of the micro light-emitting diode;

a2, length of the adhesive film layer;

b1, width of the micro light-emitting diode;

b2, width of the adhesive film layer;

A1a, first region;

A1b, second region;

I, micro light-emitting diode;

109a, residual adhesive;

300, display device.

### DETAILED DESCRIPTION OF EMBODIMENTS

### First Embodiment

A micro light-emitting element is provided in the first embodiment. By setting an etching protective layer, after laser lifting-off a micro light-emitting diode, damage to a semiconductor epitaxial stacked layer during a residual adhesive removing process can be reduced, thereby improving optoelectronic performance and reliability of the micro light-emitting element.

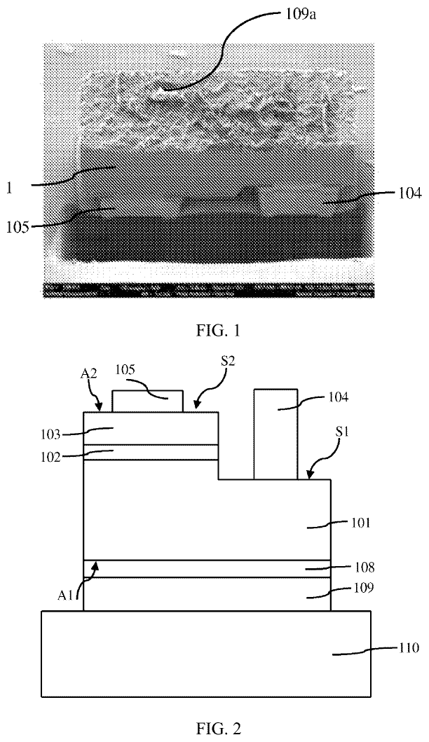

FIG. 1 and FIG. 2 illustrate schematic structural diagrams of micro light-emitting elements in the first embodiment, the micro light-emitting element includes a substrate 110 and at least one micro light-emitting diode disposed on the substrate 110; each of the at least one micro light-emitting diode is adhered on the substrate 110 through an adhesive film layer 109. The micro light-emitting diode refers to a light-emitting diode at a micrometer scale. Due to a small size of the micro light-emitting diode, a preparation process of the micro light-emitting diode is significantly different from a preparation process of a traditional light-emitting diode. The micro light-emitting diode is a substrate-free light-emitting diode, a growth substrate needs to be stripped off through a stripping process, and the micro light-emitting diode is transferred to a circuit substrate through the mass transfer technology.

The laser mass transfer technology is a commonly used mass transfer technology, which includes the following processes.

1) A side of the micro light-emitting diode is connected to the substrate 110 through the adhesive film layer 109, and the adhesive film layer 109 can be stripped off under laser exposure.

2) The other side of the micro light-emitting diode is adhered to a base with a driving circuit, the substrate 110 is separated from the micro light-emitting diode through a laser lifting-off process, and the adhesive film layer 109 is removed.

The micro light-emitting diode in the disclosure mainly refers to a size including a length, a width or a height being in a range from 2 μm to 5 μm, from 5 μm to 10 μm, from 10 μm to 20 μm, from 20 μm to 50 μm, or from 50 μm to 100 μm.

The substrate 110 includes, but is not limited to, a sapphire substrate, a glass substrate, a silicon substrate, or a silicon nitride substrate, and is preferably a transparent substrate, which is the sapphire substrate or the glass substrate. A preparation material of the adhesive film layer 109 includes polyimide or acrylic adhesive. The polyimide or acrylic adhesive can transmit through laser in an ultraviolet waveband, and can be fully decomposed by the laser in the ultraviolet waveband, ensuring that the micro light-emitting diode is not damaged by the laser. Preferably, a transmittance of the adhesive film layer 109 to light with a wavelength in a range of 400 nm to 750 nm is not less than 90%, and the adhesive film layer 109 can be fully decomposed by the laser in the ultraviolet waveband, especially an absorption rate to light with a wavelength in range of less than 360 nm is not less than 90%. A thickness of the adhesive film layer 109 is in range of 0.1 μm to 2 μm, and is preferably in a range of more than 0.5 μm and less than 1.5 μm, which ensures sufficient adhesion power between the semiconductor epitaxial stacked layer and the substrate 110.

Referring to FIG. land FIG. 2, the micro light-emitting diode includes: the semiconductor epitaxial stacked layer 1, which includes a first-type semiconductor layer 101, an active layer 102 and a second-type semiconductor layer 103 arranged sequentially in that order; the semiconductor epitaxial stacked layer 1 comprising a first surface A1 and a second surface A2 that are opposite to each other, the first-type semiconductor layer 101 being located on a side of the semiconductor epitaxial stacked layer 1 near the first surface A1, and the second-type semiconductor layer 103 being located on a side of the semiconductor epitaxial stacked layer 1 near the second surface A2; a first mesa S1, which is composed of the first-type semiconductor layer 101 exposed by recess of the semiconductor epitaxial stacked layer 1; a second mesa S2, which is composed of the second-type semiconductor layer 103; a first electrode 104, disposed on the first mesa S1 and electrically connected to the first-type semiconductor layer 101; and a second electrode 105, disposed on the second mesa S2 and electrically connected to the second-type semiconductor layer 103.

The semiconductor epitaxial stacked layer 1 can be formed on the growth substrate through methods such as physical vapor deposition (PVD), chemical vapor deposition (CVD), epitaxial growth technology, and atomic layer deposition (ALD). The semiconductor epitaxial stacked layer 1 is composed of a semiconductor material capable of emitting radiations such as ultraviolet, blue, green, yellow, red, and infrared light. Specifically, the semiconductor material can be a material in a waveband range of 200 nm to 950 nm, such as a common nitride, specifically, a gallium nitride-based semiconductor epitaxial stacked layer, which is commonly doped with aluminum, indium and other elements, and mainly provides radiation in a waveband range of 200 nm to 550 nm; or an aluminum gallium indium phosphide-based semiconductor epitaxial stacked layer or an aluminum gallium arsenide-based semiconductor epitaxial stacked layer, which mainly provides radiation in a waveband range of 550 nm to 950 nm.

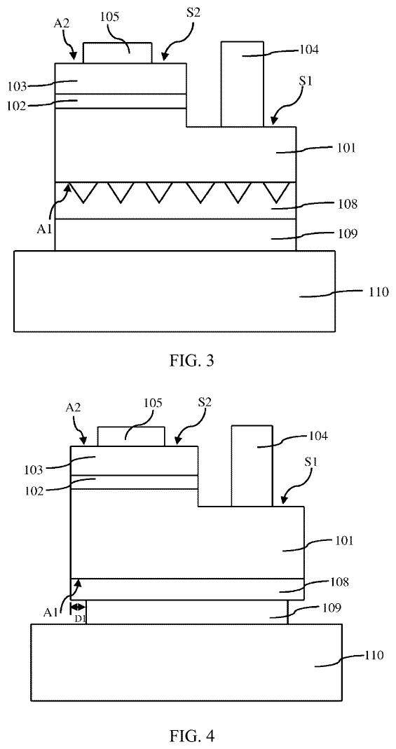

The first-type semiconductor layer 101 can be composed of III-V group compound semiconductor or II-VI group compound semiconductor and can be doped with a first dopant. The first-type semiconductor layer 101 can be composed of a semiconductor material with a chemical formula of Inₓ₁Al_{y1}Ga_{1-x1-y1}P(where 0≤X1≤1, 0≤Y1≤1, and 0≤X1+Y1≤1), such as gallium nitride (GaN), aluminum gallium nitride (AlGaN), indium gallium nitride (InGaN), indium aluminum gallium nitride (InAlGaN), or a material selected from aluminum gallium arsenide (AlGaAs), gallium phosphide (GaP), gallium arsenide (GaAs), gallium arsenide phosphide (GaAsP), and aluminum gallium indium phosphide (AlGaInP). In addition, the first dopant can be an n-type dopant, such as silicon (Si), germanium (Ge), stannum (Sn), selenium (Se), and tellurium (Te). When the first dopant is the n-type dopant, the first-type semiconductor layer 101 doped with the first dopant is an n-type semiconductor layer. The first dopant can also be a p-type dopant, such as magnesium (Mg), zinc (Zn), calcium (Ca), strontium (Sr), and barium (Ba). When the first dopant is the p-type dopant, the first-type semiconductor layer 101 doped with the first dopant is a p-type semiconductor layer. The first surface A1 of the semiconductor epitaxial stacked layer 1 is a primary light-emitting surface. In order to improve light-emitting efficiency of the micro light-emitting diode, a surface of the first-type semiconductor layer 101, facing away from the active layer 102, can be treated with roughening to form a roughened structure, as shown in FIG. 3. In some optional embodiments, the surface of the first-type semiconductor layer 101, facing away from the active layer 102, can also be treated without roughening, as shown in FIG. 2.

The active layer 102 is disposed between the first-type semiconductor layer 101 and the second-type semiconductor layer 103. The active layer 102 is a region that provides light radiation for electron and hole recombination. Different materials can be selected according to different emission wavelengths, and the active layer 102 can be a periodic structure of a single quantum well or multiple quantum wells. The active layer 102 comprises a well layer and a barrier layer, and the barrier layer has a larger bandgap than the well layer. By adjusting a composition ratio of a semiconductor material in the active layer 102, it is expected to emit light with different wavelengths.

The second-type semiconductor layer 103 is disposed on the active layer 102, and can be composed of III-V group compound semiconductor or II-VI group compound semiconductor. The second-type semiconductor layer 103 can be doped with a second dopant. The second-type semiconductor layer 103 can be composed of a semiconductor material with a chemical formula of Inₓ₂Al_{y2}Ga_{1-x2-y2}P(where 0≤X2≤1,0≤Y2≤1, and 0≤X2+Y2≤1), or a material selected from AlGaAs, GaP, GaAs, GaAsP, and AlGaInP. When the second dopant is a p-type dopant, such as Mg, Zn, Ca, Sr, and Ba, the second-type semiconductor layer 103 doped with the second dopant is a p-type semiconductor layer. The second dopant can also be an n-type dopant, such as Si, Ge, Sn, Se and Te. When the second dopant is the n-type dopant, the second-type semiconductor layer 103 doped with the second dopant is an n-type semiconductor layer. When the first-type semiconductor layer 101 is the n-type semiconductor layer, the second-type semiconductor layer 103 is the p-type semiconductor layer; conversely, when the first-type semiconductor layer 101 is the p-type semiconductor layer, the second-type semiconductor layer 103 is the n-type semiconductor layer.

The semiconductor epitaxial stacked layer 1 can also include other layer materials, such as a current spreading layer, a window layer, or an ohmic contact layer, etc., which are set as different layers according to different doping concentrations or component contents. In the first embodiment, the semiconductor epitaxial stacked layer 1 is composed of an AlGaInP-based material, and the semiconductor epitaxial stacked layer 1 radiates red light as an example, but the disclosure is not limited to a red light micro light-emitting diode; the disclosure is also applicable to a blue-green light micro light-emitting diode.

In order to improve reliability of the micro light-emitting diode, insulating medium layers (not shown in the figure) are preferably disposed on the first mesa S1 and the second mesa S2 of the micro light-emitting diode. A material of the insulating medium layers can use a Bragg reflector (DBR) structure, which is formed by alternately stacking two insulating medium layer materials with different refractive indexes. The DBR structure is composed of a non-metal material such as silicon dioxide (SiO₂), silicon nitride (SiNx), titanium dioxide (TiO₂), aluminum oxide (Al₂O₃), etc. The DBR can reflect light radiated from the semiconductor epitaxial stacked layer 1 towards the light-emitting surface, thereby improving the light-emitting efficiency of the micro light-emitting diode. A thickness of the material of the insulating medium layers is in a range of more than 0.5 μm. In some embodiments, a preferred thickness range of the insulating medium layers on the first mesa S1 is in a range of 0.5 μm to 1.5 μm.

The first electrode 104 and the second electrode 105 are located on an opposite side of a light-emitting side. The first electrode 104 and the second electrode 105 can contact with external electrical connection elements through the opposite side of the light-emitting side, forming a flip-chip structure. Therefore, the first electrode 104 and the second electrode 105 include ohmic contact parts and pad electrodes (not shown in the figure), and the pad electrodes can be at least one layer, such as gold, aluminum, or silver to achieve die bonding of the first electrode 104 and the second electrode 105. The first electrode 104 and the second electrode 105 can be of equal or unequal height, and pad metal layers of the first electrode 104 and the second electrode 105 do not overlap in a thickness direction. The substrate 110 is separated from the micro light-emitting diode using the laser lifting-off process, and a dissection surface of the laser is an interface between the substrate 110 and the adhesive film layer 109. After the micro light-emitting element is stripped off form the substrate 110 by the laser, a part of the adhesive film layer 109 will be stripped off along with the substrate 110, and a remaining part of the adhesive film layer 109 will remain on the first surface A1 of the semiconductor epitaxial stacked layer 1. A residual adhesive film layer on the first surface A1 of the semiconductor epitaxial stacked layer 1 is referred to as residual adhesive 109a, as shown in FIG. 1. A presence of the residual adhesive 109a can affect optoelectronic performance of the micro light-emitting diode, so a plasma method or an iterative closest point (ICP) method need to be used to remove the residual adhesive 109a. In order to reduce the damage to the semiconductor epitaxial stacked layer 1 during the residual adhesive removing process, an etching protective layer 108 is disposed between the adhesive film layer 109 and the first surface A1 of the semiconductor epitaxial stacked layer 1 in the first embodiment. The etching protective layer 108 can isolate the semiconductor epitaxial stacked layer 1 from etching gas or etching solution during the residual adhesive etching removing process, protecting the semiconductor epitaxial stacked layer 1 from damage. In addition, the etching protective layer 108 can also serve as a protective layer to isolate moisture from the semiconductor epitaxial stacked layer 1, thereby improving the reliability of the micro light-emitting diode.

The etching protective layer 108 is composed of silicon dioxide, silicon nitride, aluminum oxide, titanium oxide, or magnesium fluoride. A thickness of the etching protective layer 108 is in a range of 500 Å to 10,000 Å, and is preferably in a range of 5,000 Å to 8,000 Å, thereby achieving effective protection of the semiconductor epitaxial stacked layer.

### Second Embodiment

As shown in FIG. 4 and FIG. 6, differing from FIG. 2 in the first embodiment, in the second embodiment, the adhesive film layer 109 is preferably disposed in a first region A1a of the first surface A1 of the micro light-emitting diode, and the first surface A1 further includes a second region A1b; the first region A1a is located in the second region A1b, and the second region A1b is located at an edge of the first surface A1. The adhesive film layer 109 does not exceed the edge of the first surface A1. It should be noted that the adhesive film layer 109 not exceeding the edge of the first surface A1 means that, in a top view of a product from a vertical direction, a projection of the adhesive layer 109 is located in the first surface A1 of the semiconductor epitaxial stacked layer. Specifically, a distance D1 from the adhesive film layer 109 to the edge of the first surface A1 of the semiconductor epitaxial stacked layer is in a range of 0.3 μm to 6 μm, and is preferably in a range of more than 1.5 μm and less than 5 μm. when the distance D1 is too large, it cannot ensure adhesion between the substrate 110 and the semiconductor epitaxial stacked layer, which can lead to detachment of the micro light-emitting diode during transfer and transportation; when the distance D1 is too small, it cannot effectively improve a center of gravity of the micro light-emitting element, nor can it improve a chip flipping problem during a transfer process of the micro light-emitting element.

In the second embodiment, the distance D1 between the adhesive film layer 109 and the first surface A1 of the semiconductor epitaxial stacked layer can be changed with the size of the micro light-emitting diode. In some optional embodiments, a length a2 or a width b2 of the adhesive film layer 109 is 60% to 85% of a length a1 or a width b1 of the micro light-emitting diode. In some optional embodiments, an covered area of the first surface A1 of the semiconductor epitaxial stacked layer by the adhesive film 109 is 60% to 90% of an area of the first surface A1 of the semiconductor epitaxial stacked layer, and is preferably 70% to 80%, which ensures sufficient adhesion power between the semiconductor epitaxial stacked layer and the substrate 110, thereby improving a problem of micro light-emitting diode flipping during the transfer process, and enhancing a transfer yield rate of the micro light-emitting diode.

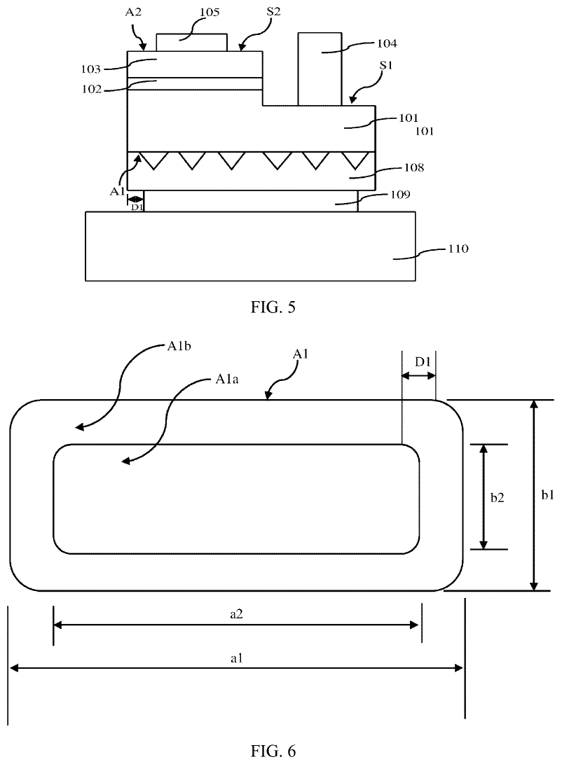

In some optional embodiments, the first surface A1 of the semiconductor epitaxial stacked layer is preferably provided with the roughened structure, which can improve the light-emitting efficiency of the semiconductor epitaxial stacked layer, as shown in FIG. 5.

In the second embodiment, by inwardly reducing the adhesive film layer 109 with a certain width, a weight of the micro light-emitting diode can be concentrated at a center of the micro light-emitting diode. This reduces the generation of flip over of the micro light-emitting diode during the transfer process, after the laser lifting-off the micro light-emitting element, thereby improving the transfer yield rate of the micro light-emitting diode.

In some optional embodiments, the first surface A1 of the semiconductor epitaxial stacked layer of the micro light-emitting element may not be covered by the etching protective layer 108, which is not limited to these embodiments.

### Third Embodiment

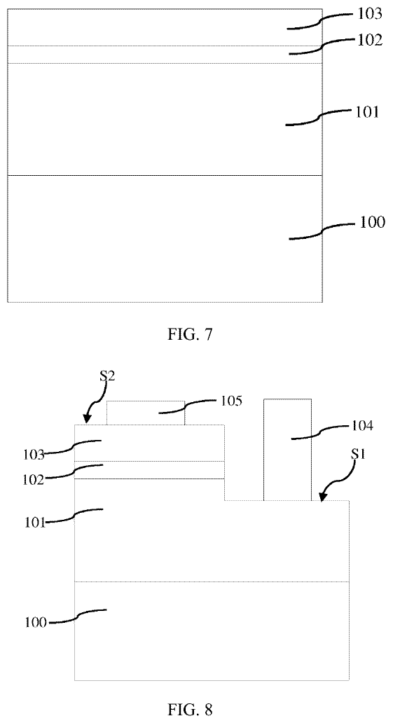

FIG. 7 through FIG. 16 illustrates schematic structural diagrams associated with a preparation process of a micro light-emitting element according to the third embodiment of the disclosure. A preparation method of the micro light-emitting element of the disclosure is described in detail below in combination with the schematic diagrams.

Firstly, as shown in FIG. 7, an epitaxial structure is provided, which specifically includes the following steps: the growth substrate 100, preferably a gallium arsenide substrate, being provided, and the semiconductor epitaxial stacked layer being grown epitaxially on the growth substrate 100 through an epitaxial process such as metal organic chemical vapor deposition (MOCVD). The semiconductor epitaxial stacked layer includes the first-type semiconductor layer 101, the second-type semiconductor layer 103 and the active layer 102 located between the first-type semiconductor layer 101 and the second-type semiconductor layer 103, which are sequentially stacked on a surface of the growth substrate 100. The semiconductor epitaxial stacked layer is preferably composed of an AlGaInP-based material, and the active layer 102 radiates red light.

Then, as shown in FIG. 8, a part of the semiconductor epitaxial stacked layer is removed by a dry etching method to form the first mesa S1 and the second mesa S2. The first electrode 104 and the second electrode 105 are formed on the first mesa S1 and the second mesa S2, respectively. Therefore, the first electrode 104 and the second electrode 105 are electrically connected to the first-type semiconductor layer 101 and the second-type semiconductor layer 103, respectively.

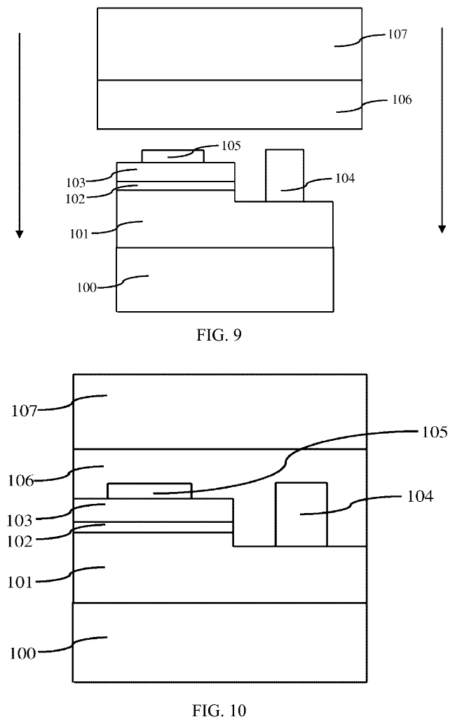

Then, as shown in FIG. 9 and FIG. 10, a side of the semiconductor epitaxial stacked layer facing away from the growth substrate 100 is fixed on a first transfer substrate 107, the first transfer substrate 107 is provided with an adhesive layer 106, and the adhesive layer 106 is adhered with the semiconductor epitaxial stacked layer.

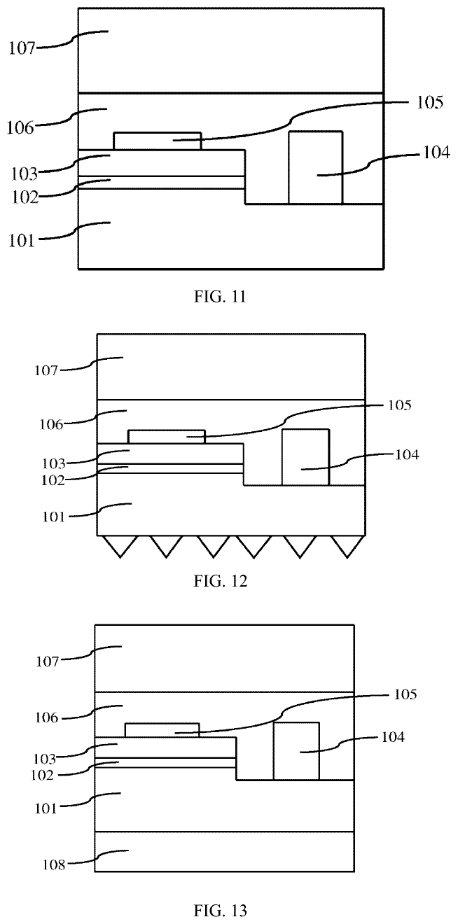

Then, as shown in FIG. 11, the growth substrate 100 is removed to expose the first-type semiconductor layer 101. In some optional embodiments, the first-type semiconductor layer 101 that is exposed after removing the growth substrate 100 from the semiconductor epitaxial stacked layer is preferably roughened. A roughening method includes a wet etching method or the dry etching method, and the roughened structure is obtained as shown in FIG. 12.

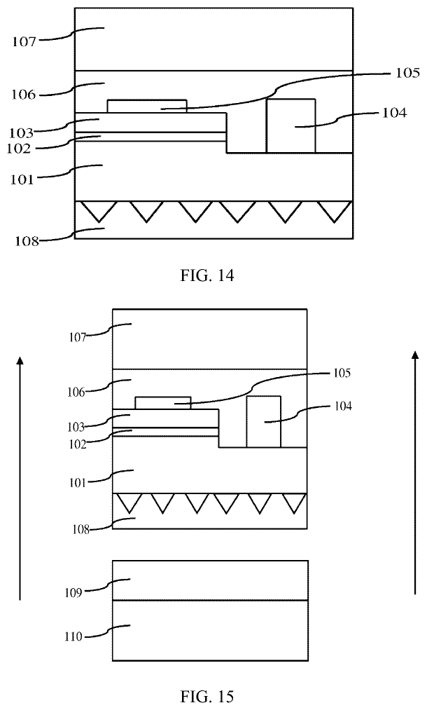

Next, as shown in FIG. 13 and FIG. 14, the etching protective layer 108 is formed on the surface of the semiconductor epitaxial stacked layer facing away from the first transfer substrate 107. The etching protective layer 108 covers at least the first surface A1 of the semiconductor epitaxial stacked layer, and can also extend to cover sidewalls of the semiconductor epitaxial stacked layer. The first surface A1 of the semiconductor epitaxial stacked layer can be roughened or unroughened. In the third embodiment, the first surface A1 of the semiconductor epitaxial stacked layer 1 is roughened, which is not limited to the third embodiment.

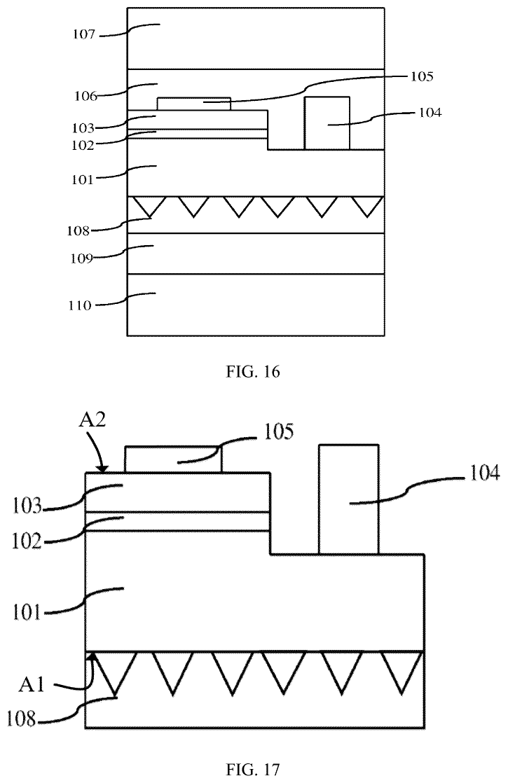

Next, as shown in FIG. 15 and FIG. 16, the first-type semiconductor layer 101 is pressed and fixed in the adhesive film layer 109 of the substrate 110, thus the micro light-emitting diode is fixed on the substrate 110 through the adhesive film layer 109.

Then, the first transfer substrate 107 and the adhesive layer 106 are removed, thus the micro light-emitting diode is fixed on the substrate 110 from the first transfer substrate 107, which inverts electrode surfaces of the micro light-emitting diode upward to obtain the micro light-emitting element as shown in FIG. 3.

In some optional embodiments, a partial edge area of the adhesive film layer 109 is removed, causing a size of the adhesive film layer 109 to reduce inwardly, thereby concentrating the center of gravity of the micro light-emitting diode at the center of the micro light-emitting diode. This reduces the generation of flip over of the micro light-emitting diode during the transfer process after the laser lifting-off the micro light-emitting element, which is caused by an uneven center of gravity, thereby improving the transfer yield rate of the micro light-emitting diode. The micro light-emitting element as shown in FIG. 5 can be obtained after inward reduction. The inward reduction of the adhesive film layer 109 is performed using an etching method, which includes a dry etching method or a wet etching method. In the third embodiment, the dry etching method is preferred. After an etching process, a covered area of the adhesive film layer 109 does not exceed a surface of the semiconductor epitaxial stacked layer. The adhesive film layer 109 is covered in the first region A1a of the first surface A1 of the semiconductor epitaxial stacked layer, while the adhesive film layer 109 is removed in the second region A1b from a periphery. The distance DI from the adhesive film layer 109 to the edge of the first surface A1 of the semiconductor epitaxial stacked layer is in a range of 0.3 μm and 6 μm, and is preferably in a range of more than 1.5 μm and less than 5 μm. When the distance D1 is too large, it cannot ensure the adhesion between the substrate 110 and the semiconductor epitaxial stacked layer, which can lead to the detachment of the micro light-emitting diode during the transfer and transportation. When the distance D1 is too small, it cannot effectively improve the center of gravity of the micro light-emitting element, nor can it improve the chip flipping problem during the transfer process. A chip structure in the third embodiment forms a micro light-emitting array fixed on a wafer for transportation and delivery, to be used by downstream users for laser pickup.

In some methods of some embodiments, the preparation method further includes the following steps. The adhesive film layer 109 is decomposed by the laser, a laser action area is located at the interface between the adhesive layer 109 and the substrate 110, and the part of the adhesive layer 109, that is, the residual adhesive 109a, is separated from the substrate 110 together with the micro light-emitting diode. In this step, the laser wavelength is preferably the ultraviolet waveband of non-visible light. The adhesive film layer 109 is preferably designed to transmit light with the wavelength in the range of 400 nm to 750 nm, and the transmittance in air is not less than 90%. The material of the adhesive film layer 109, as mentioned in the aforementioned steps, can be polyimide or acrylic adhesive, which absorbs light with the wavelength in the range of less than 360 nm at the absorption rate of no less than 90% and can be sufficiently decomposed by the laser in the ultraviolet waveband, thus preventing the damage to the semiconductor epitaxial stacked layer. Subsequently, the residual adhesive 109a on a surface of the micro light-emitting diode is removed by etching. The etching protective layer 108 covering the first surface A1 of the semiconductor epitaxial stacked layer can reduce the damage to the semiconductor epitaxial stacked layer during the residual adhesive removing process after the laser lifting-off of the micro light-emitting diode, thereby enhancing the optoelectronic performance and the reliability of the micro light-emitting element.

### Fourth Embodiment

In the fourth embodiment, the micro light-emitting diode is provided. A minimum side length of the micro light-emitting diode is in a range of 50 μm to 100 μm, or in a range of less than 50 μm, and is preferably in the range of less than 50 μm in the fourth embodiment.

As shown in FIG. 17, the micro light-emitting diode includes the semiconductor epitaxial stacked layer, the first electrode 104 and the second electrode 105. The semiconductor epitaxial stacked layer includes the first-type semiconductor layer 101, the active layer 102 and the second-type semiconductor layer 103 arranged sequentially in that order. The semiconductor epitaxial stacked layer comprises the first surface A1 and the second surface A2 that are opposite to each other, the first-type semiconductor layer 101 is close to the first surface A1 of the semiconductor epitaxial stacked layer, and the second-type semiconductor layer 103 is close to the second surface A2 of the semiconductor epitaxial stacked layer. The first electrode 104 and the second electrode 105 of the micro light-emitting diode are located on a same side of the semiconductor epitaxial stacked layer, and the first surface A1 of the semiconductor epitaxial stacked layer is the primary light-emitting surface. The first surface A1 of the semiconductor epitaxial stacked layer is covered with the etching protective layer 108, and the etching protective layer is composed of silicon dioxide, silicon nitride, aluminum oxide, titanium oxide, or magnesium fluoride. The thickness of the etching protective layer 108 is in a range of 500 Å to 10,000 Å, and is preferably in a range of 5,000 Å to 8,000 Å, which provides the effective protection of the semiconductor epitaxial stacked layer. Additionally, the etching protective layer 108 serves as the protective layer to isolate the moisture from the semiconductor epitaxial stacked layer, improving the optoelectronic performance and the reliability of the micro light-emitting diode.

### Fifth Embodiment

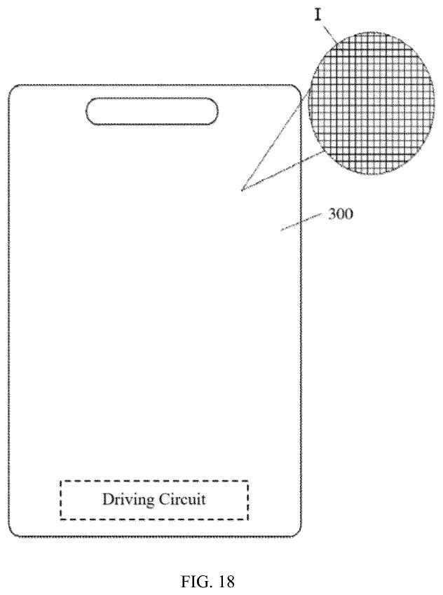

Referring to FIG. 18, a display device 300 is provided in the fifth embodiment. The display device 300 includes multiple micro light-emitting diodes I arranged in arrays as described in any one of the aforementioned embodiments. A part of the multiple micro light-emitting diodes I is displayed in a schematic way of enlarged display.

In the fifth embodiment, the display device 300 is a display device corresponding to a display screen of an intelligent phone. In other embodiments, the display device 300 can also be a display device of other electronic products, such as a computer display device, or an intelligent wearable electronic product display device.

Due to the multiple micro light-emitting diodes I as described in the aforementioned embodiments, the display device 300 possesses advantages brought by the multiple micro light-emitting diodes I in the aforementioned embodiments.

What is claimed is:

1. A micro light-emitting element, comprising:
a substrate; and
at least one micro light-emitting diode, disposed on the substrate; wherein each of the at least one micro light-emitting diode comprises:
a semiconductor epitaxial stacked layer, comprising a first-type semiconductor layer, an active layer and a second-type semiconductor layer sequentially arranged in that order; wherein the semiconductor epitaxial stacked layer has a first surface and a second surface that are opposite to each other, the first surface is located on a side of the semiconductor epitaxial stacked layer near the first-type semiconductor layer, the second surface is located on a side of the semiconductor epitaxial stacked layer near the second-type semiconductor layer, and the first surface faces towards the substrate; and
an adhesive film layer, disposed between the substrate and the first surface of the semiconductor epitaxial stacked layer;
wherein an etching protective layer is disposed between the adhesive film layer and the first surface of the semiconductor epitaxial stacked layer.

2. The micro light-emitting element as claimed in claim 1, wherein the etching protective layer is composed of silicon dioxide, silicon nitride, aluminum oxide, titanium oxide, or magnesium fluoride.

3. The micro light-emitting element as claimed in claim 1, wherein each of the at least one micro light-emitting diode is remained with the etching protective layer after the micro light-emitting element is stripped off from the substrate.

4. The micro light-emitting element as claimed in claim 1, wherein the etching protective layer is configured to protect the semiconductor epitaxial stacked layer of each of the at least one micro light-emitting diode from etching during a residual adhesive removing process after the substrate is stripped off. 5, The micro light-emitting element as claimed in claim 1, wherein a thickness of the etching protective layer is in a range of 500 angstroms (Å) to 10,000 Å.

6. The micro light-emitting element as claimed in claim 1, wherein a transmittance of the adhesive film layer to light with a wavelength in a range of 400 nanometers (nm) to 750 nm is greater than a transmittance to light with a wavelength in a range of less than 360 nm.

7. The micro light-emitting element as claimed in claim 1, wherein an absorption rate of the adhesive film layer to light with a wavelength in a range of less than 360 nm is greater than or equal to 90%, and the adhesive film layer is configured to be decomposed after absorbing ultraviolet laser.

8. The micro light-emitting element as claimed in claim 1, wherein a material of the adhesive film layer comprises polyimide or acrylic adhesive.

9. The micro light-emitting element as claimed in claim 1, wherein a thickness of the adhesive film layer is in a range of 0.1 micrometers (μm) to 0.2 μm.

10. The micro light-emitting element as claimed in claim 1, wherein a distance from the adhesive film layer to an edge of the first surface of the semiconductor epitaxial stacked layer is in a range of 0.3 μm to 4 μm.

11. The micro light-emitting element as claimed in claim 1, wherein a length or a width of the adhesive film layer is 60% to 85% of a length or a width of each of the at least one micro light-emitting diode.

12. The micro light-emitting element as claimed in claim 1, wherein a covered area of the first surface of the semiconductor epitaxial stacked layer by the adhesive film layer is 60% to 90% of an area of the first surface of the semiconductor epitaxial stacked layer.

13. The micro light-emitting element as claimed in claim 1, wherein each of the at least one micro light-emitting diode further comprises:
a first electrode, disposed on a first mesa and electrically connected to the first-type semiconductor layer; and
a second electrode, disposed on a second mesa and electrically connected to the second-type semiconductor layer.

14. The micro light-emitting element as claimed in claim 1, wherein a width or a length or a height of each of the at least one micro light-emitting diode is in a range from 2 μm to 5 μm, from 5 μm to 10 μm, from 10 μm to 20 μm, from 20 μm to 50 μm, or from 50 μm to 100 μm.

15. A micro light-emitting diode, comprising:
a semiconductor epitaxial stacked layer, comprising a first-type semiconductor layer, an active layer and a second-type semiconductor layer sequentially arranged in that order; wherein the semiconductor epitaxial stacked layer comprises a first surface and a second surface that are opposite to each other, the first-type semiconductor layer is located on a side of the semiconductor epitaxial stacked layer near the first surface, and the second-type semiconductor layer is located on a side of the semiconductor epitaxial stacked layer near the second surface;
an etching protective layer, disposed covering the first surface of the semiconductor epitaxial stacked layer;
a first electrode, electrically connected to the first-type semiconductor layer; and
a second electrode, electrically connected to the second-type semiconductor layer.

16. The micro light-emitting diode as claimed in claim 15, wherein a material of the etching protective layer is silicon dioxide, silicon nitride, aluminum oxide, titanium oxide, or magnesium fluoride; and a thickness of the etching protective layer is in a range of 500 Å to 10,000 Å.

17. The micro light-emitting diode as claimed in claim 15, wherein the first electrode and the second electrode of the micro light-emitting diode are located on a same side of the semiconductor epitaxial stacked layer.

18. The micro light-emitting diode as claimed in claim 15, wherein the first-type semiconductor layer is composed of a semiconductor material with a chemical formula of Inₓ₁Al_{y1}Ga_{1-x1-y1}P, where 0≤X1≤1, 0≤Y1≤1, and 0≤X1+Y1≤1.

19. The micro light-emitting diode as claimed in claim 15, wherein the second-type semiconductor layer is composed of a semiconductor material with a chemical formula of Inₓ₂Al_{y2}Ga_{1-x2-y2}P, where 0≤X2≤1, 0≤Y2≤1, and 0≤X2+Y2≤1.

20. A display device, comprising:
a base with a driving circuit, and
the micro light-emitting diode as claimed in claim 15, disposed on the base, wherein the micro light-emitting diode is electrically connected to the driving circuit.
